(19) United States
(12) Patent Application Publication
(10) Pub. No.: US 2023/0110908 A1
(43) Pub. Date: Apr. 13, 2023

(54) ELECTRO-OPTICAL DEVICE AND ELECTRONIC DEVICE

(71) Applicant: SEIKO EPSON CORPORATION, Tokyo (JP)

(72) Inventors: Tsuyoshi TAMURA, HARA-MURA SUWA-GUN (JP); Shinichi IWATA, CHINO-SHI (JP); Takehiko KUBOTA, MATSUMOTO-SHI (JP)

(73) Assignee: SEIKO EPSON CORPORATION, Tokyo (JP)

(21) Appl. No.: 17/954,311

(22) Filed: Sep. 27, 2022

(30) Foreign Application Priority Data
Sep. 29, 2021 (JP) 2021-158903

(51) Int. Cl. H01L 51/52; H01L 27/32

(52) U.S. Cl. CPC H01L 51/5265; H01L 27/322; H01L 27/3223; H01L 51/5218

(57) ABSTRACT

A region where a pixel electrode and a light emitting layer overlap with each other in plan view includes: a light emitting region where the pixel electrode and the light emitting layer are in contact with each other; a pixel contact region where the pixel electrode and a relay layer overlap with each other in plan view; and a dummy contact region that overlaps with the pixel electrode, the dummy relay layer, and a common electrode. In a direction of a thickness of a substrate, a distance between a reflection layer and the pixel electrode in the dummy contact region is longer than a distance between the reflection layer and the pixel electrode in the pixel contact region. A color layer is provided at a portion that overlaps with the dummy contact region in plan view.

The present application is based on, and claims priority from JP Application Serial Number 2021-158903, filed on Sep. 29, 2021, the disclosure of which is hereby incorporated by reference herein in its entirety.

### BACKGROUND

### 1. Technical Field

The present disclosure relates to an electro-optical device and an electronic device.

### 2. Related Art

For example, an electro-optical device using an OLED is known as a light emitting element. The OLED stands for an organic light emitting diode. This electro-optical device includes a pixel portion including a transistor or the like configured to cause an electric current to flow through the light emitting element. At a substrate made of a semiconductor, the pixel portion is provided so as to correspond to each pixel of an image to be displayed. The OLED is configured such that a light emitting layer is interposed between a pixel electrode and a common electrode, and emits light at luminance according to an electric current flowing through the light emitting layer. With this configuration, in a pixel contact region, the pixel electrode is coupled to a lower wiring line, and the lower wiring line is electrically coupled to the transistor described above.

In addition, there is a configuration in which each pixel portion is provided for every three colors of R (red), G (green), and B (blue). Regarding this configuration, JP-A-2019-029188 proposes a technique of adjusting an optical distance between a pixel electrode and a reflection layer for each pixel portion (color).

With the technique described in JP-A-2019-029188, R has the longest wavelength of the three colors, and the upper surface position (observer-side position) of the light emitting layer at the pixel portion for R is the highest in the light emitting region or the pixel contact region, as compared with the other two colors.

However, in a process of manufacturing the electro-optical device, there is a problem in that: when pressing toward a substrate occurs for some reasons, this pressing leads to a reduction in the thickness of the light emitting layer; and this results in a reduction in the resistance of the light emitting layer, which causes abnormal light emission that is not expected in the designing phase.

### SUMMARY

An electro-optical device according to one aspect of the present disclosure includes a substrate, a first light emitting element including a common electrode, a first pixel electrode, and a light emitting layer, a first reflection layer provided between the substrate and the first pixel electrode, and a first relay layer configured to electrically couple the first reflection layer and the first pixel electrode, in which, the first light emitting element includes, in plan view, in a region where the first pixel electrode and the light emitting layer overlap with each other, a first light emitting region where the first pixel electrode and the light emitting layer are in contact with each other, a first pixel contact region where the first pixel electrode and the first relay layer overlap with each other in plan view, and a non-coupling region disposed at an outside of the first light emitting region in plan view and differing from the first pixel contact region, in a direction of a thickness of the substrate, a distance between the first reflection layer and the first pixel electrode in the non-coupling region is longer than a distance between the first reflection layer and the first pixel electrode in the first pixel contact region, and a first color layer is provided so as to overlap with the non-coupling region in plan view and is configured to block light emitted from the non-coupling region.

### BRIEF DESCRIPTION OF THE DRAWINGS

FIG. 1 is a block diagram illustrating a configuration of an electro-optical device according to a first embodiment.

FIG. 2 is a circuit diagram illustrating a pixel portion in the electro-optical device.

FIG. 3 is a timing chart illustrating operation of the electro-optical device.

FIG. 4 is a plan view illustrating a layout of pixel portions in the electro-optical device.

FIG. 5 is a plan view illustrating pixel electrodes in the electro-optical device.

FIG. 6 is a plan view illustrating a layout of color layers in the electro-optical device.

FIG. 7 is a cross-sectional view illustrating main components including a pixel contact region in a pixel portion for R.

FIG. 8 is a cross-sectional view illustrating main components including a pixel contact region in a pixel portion for G.

FIG. 9 is a cross-sectional view illustrating main components including a pixel contact region in a pixel portion for B.

FIG. 10 is a cross-sectional view illustrating main components including a dummy contact region in a pixel portion.

FIG. 11 is a cross-sectional view illustrating main components including a dummy contact region in a pixel portion according to a second embodiment.

FIG. 12 is a cross-sectional view illustrating main components including a dummy contact region in a pixel portion according to a first modification example.

FIG. 13 is a cross-sectional view illustrating main components including a dummy contact region in a pixel portion according to a second modification example.

FIG. 14 is a perspective view illustrating a head-mounted display using an electro-optical device.

FIG. 15 is a diagram illustrating an optical configuration of the head-mounted display.

### DESCRIPTION OF EXEMPLARY EMBODIMENTS

Below, an electro-optical device according to an embodiment of the present disclosure will be described with reference to the drawings. It should be noted that, in each of the drawings, the dimension and scale of each portion is set so as to appropriately differ from the actual dimension and scale of each corresponding portion. In addition, the embodiments described below are preferred specific examples, and various types of technically preferred limitation are applied. However, the scope of the present disclosure is not limited to these modes unless there is description that particularly limits the present disclosure.

### First Embodiment

FIG. 1 is a block diagram illustrating the configuration of an electro-optical device 10 according to a first embodiment.

The electro-optical device 10 is, for example, a micro display panel configured to display a color image in a head-mounted display or the like. The electro-optical device 10 includes a plurality of pixel portions, a driving circuit configured to drive the pixel portions, the structures, and the like, each of which is formed at a semiconductor substrate. In the present embodiment, a silicon substrate is used for the semiconductor substrate. However, it may be possible to use other semiconductor substrates.

As illustrated in FIG. 1, the electro-optical device 10 is generally divided into a control circuit 30, a data-signal outputting circuit 50, a display region 100, and a scanning line drive circuit 120.

In the display region 100, m rows of scanning lines 12 are provided along the X direction in the drawing, and (3n) columns of data lines 14 are provided along the Y direction so as to maintain electrical insulation from each of the scanning lines 12. Note that each of the “m” and the “n” is an integer equal to or more than 2.

In the display region 100, pixel portions 110 are provided so as to correspond to intersections of m rows of scanning lines 12 and (3 n) columns of data lines 14. Thus, the pixel portions 110 are arrayed in a matrix of m rows (vertical direction) × (3 n) columns (horizontal direction). In the matrix array, each row may be referred to as the first, second, third, ..., (m-1)-th, or m-th row in the order from the top in the drawing, for the purpose of making distinction between individual rows. Similarly, each column may be referred to as the first, second, third, ..., (3 n-2)-th, (3 n-1)-th, or (3 n)-th column in the order from the left in the drawing, for the purpose of making distinction between individual columns in the matrix.

Note that an integer i not less than 1 and not more than m is used in order to describe the scanning lines 12 in a generalized manner. Similarly, an integer j not less than 1 and not more than (3 n) is used in order to describe the data lines 14 in a generalized manner.

The control circuit 30 controls each component on the basis of video data Vid or a synchronization signal Sync supplied from a host device. Specifically, the control circuit 30 generates various types of control signals used to control each component.

The video data Vid designates a gray scale level of a pixel in an image to be displayed, for example, by 8 bits. The synchronization signal Sync contains a vertical synchronization signal used to give an instruction to start vertical scanning of the video data Vid, a horizontal synchronization signal used to given an instruction to start horizontal scanning, and a dot clock signal indicating timing for one pixel of the video data.

In the present embodiment, a pixel of an image to be displayed corresponds, one by one, to the pixel portion 110 in the display region 100.

The property of luminance of a gray scale level indicated by the video data Vid supplied from the host device does not necessarily match the property of luminance at the OLED included in the pixel portion 110. Thus, the control circuit 30 converts 8 bits of the video data Vid to increase, for example, to 10 bits, and outputs it as video data Vdata, in order to cause the OLED to emit light at the luminance corresponding to the gray scale level indicated by the video data Vid. For this reason, the 10-bit video data Vdata is data corresponding to the gray scale level designated in the video data Vid.

Note that, in this up-conversion, a look-up table is used. The look-up table stores, in advance, a corresponding relationship between 8-bit video data Vid serving as input and 10-bit video data Vdata serving as output.

The scanning line drive circuit 120 is a circuit configured to drive, one row by one row, the pixel portions 110 arrayed in m rows and (3 n) columns in accordance with control by the control circuit 30. For example, the scanning line drive circuit 120 sequentially supplies the scanning lines 12 in the first, second, third, ..., (m-1)-th, and m-th rows with scanning signals /Gwr(1), /Gwr(2), ..., /Gwr(m-1), and /Gwr(m). In general, the “/Gwr(i)” represents a scanning signal supplied to a scanning line 12 in the i-th row.

The data-signal outputting circuit 50 is a circuit configured to output a data signal through the data line 14 in accordance with control by the control circuit 30 to a pixel portion 110 disposed in a row selected by the scanning line drive circuit 120. The data signal is a voltage signal obtained by converting 10-bit video data Vdata into an analog signal. That is, the data-signal outputting circuit 50 converts, into analog data, the video data Vdata for one row corresponding to pixel portions 110 in the first to (3 n)-th columns in the selected row, and outputs it to the data lines 14 at the first to (3 n)-th columns in this order.

In the drawing, data signals outputted to the data lines 14 in the first, second, third, ..., (3 n-2)-th, (3 n-1)-th, and (3 n)-th columns are denoted with Vd(1), Vd(2), Vd(3), ..., Vd(3 n-2), Vd(3 n-1), and Vd(3 n), respectively. In general, the potential of the data line 14 in the j-th column is referred to as Vd(j).

In addition, the two-dimensional plane defined by the X direction and the Y direction is a substrate surface of the semiconductor substrate. The Z direction is perpendicular to the X direction and the Y direction, and indicates a direction in which light emitted from the OLED exits.

Note that, in the present description, the expression “plan view” represents viewing the semiconductor substrate from a direction opposite from the Z direction.

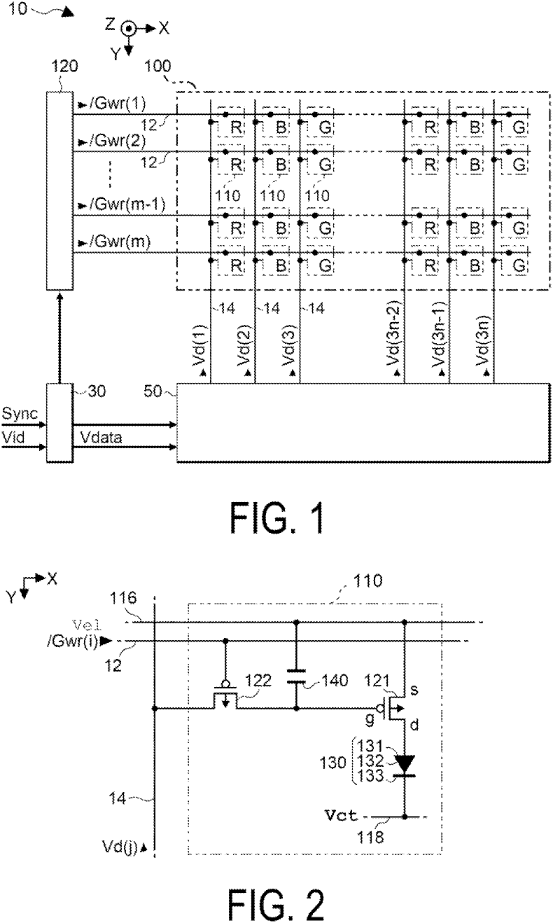

In the display region 100, the pixel portion 110 is configured such that a pixel portion 110 for R, a pixel portion 110 for B, and a pixel portion 110 for G are arrayed along the X direction, and pixel portions 110 for the same color are arrayed along the Y direction, from the electrical viewpoint, as illustrated in FIG. 2. Thus, when focus is placed on the data line 14 in a certain column, this data line 14 corresponds to pixel portions 110 for the same color. Note that one color is represented by additive color mixing of RBB pixel portions 110 adjacent in the X direction. Thus, the pixel portion 110 should be called a sub-pixel portion in the strict sense. However, for the purpose of convenience of explanation, the pixel portion 110 is referred to as a pixel portion.

Note that the layout of pixel portions 110 illustrated in FIG. 1 is provided from the electrical viewpoint. In reality, however, the pixel portion 110 for R and the pixel portion 110 for B are arrayed in the same column, as illustrated in FIG. 4 that will be described later. When the data line 14 coupled to the pixel portion 110 for R is disposed at the left and the data line 14 coupled to the pixel portion 110 for B is disposed at the right, the array of pixel portions 110 from the electrical viewpoint can be regarded as the same as that in FIG. 1.

FIG. 2 is a diagram illustrating the electrical configuration of the pixel portion 110 in the electro-optical device 10. Pixel portions 110 arrayed in 1080 rows and (3n) columns are electrically identical to each other. Thus, the pixel portion 110 will be described by using a pixel portion 110 disposed at the i-th row and j-th column as a representative pixel portion.

As illustrated in the drawing, the pixel portion 110 includes p-channel MOS type transistors 121 and 122, an OLED 130, and a capacitance element 140 from the electrical viewpoint.

Note that, in the description of the pixel portion 110, the expression “from the electrical viewpoint” is used when mentioning a plurality of components that constitute the pixel portion 110 and the relationship of coupling of the plurality of components to each other. The reason for using such expression is because, from the mechanical or physical viewpoint, the pixel portion 110 includes components that do not contribute to electrical coupling relationship.

The OLED 130 serves as one example of a light emitting element, and is configured such that a light emitting layer 132 is interposed between a pixel electrode 131 and a common electrode 133. The pixel electrode 131 functions as anode, and the common electrode 133 functions as cathode. Note that, although the OLED 130 will be described in detail later, when an electric current flows from the anode toward the cathode, a positive hole injected from the anode and an electron injected from the cathode are re-bonded at the light emitting layer 132 to generate exciton, whereby white light is generated.

The generated white light resonates at an optical resonator comprised, for example, of a reflection layer that is not illustrated in FIG. 2 and a semi-reflective and semitransparent layer. Then, light having a resonance wavelength set so as to correspond to any of colors of R(red), G(green), and B(blue) is outputted. A color filter corresponding to the color is provided at the side where light is outputted from the optical resonator. With this configuration, the light outputted from the OLED 130 is colored through the optical resonator and the color filter, and is visually recognized by an observer.

At a transistor 121 of a pixel portion 110 at the i-th row and j-th column, the gate node g is coupled to the drain node of the transistor 122, the source node is coupled to a power supplying line 116 at a voltage Vel, and the drain node is coupled to the pixel electrode 131 serving as the anode of the OLED 130.

At a transistor 122 of the pixel portion 110 at the i-th row and j-th column, the gate node is coupled to the scanning line 12 in the i-th row, and the source node is coupled to the data line 14 in the j-th column. The common electrode 133 functioning as the cathode of the OLED 130 is coupled to a power supplying line 118 at a voltage Vct. Furthermore, since the electro-optical device 10 is formed at a silicon substrate, substrate potentials of the transistors 121 and 122 are set, for example, at a potential corresponding to the voltage Vel.

From the electrical viewpoint, the pixel portions 110 illustrated in FIG. 2 are equal between RGB. Thus, general description has been made without specifying any particular color. However, next, from the structural viewpoint, the pixel portion 110 differs from color to color. For this reason, when description is made by making distinction between colors, the pixel portion 110 is referred to as a pixel portion 110R, 110G, 110B. Similarly, when description is made by making distinction between colors, the OLED 130 and the pixel electrode 131 are referred to as an OLED 130R, 130G, 130B and a pixel electrode 131R, 131G, 131B, respectively.

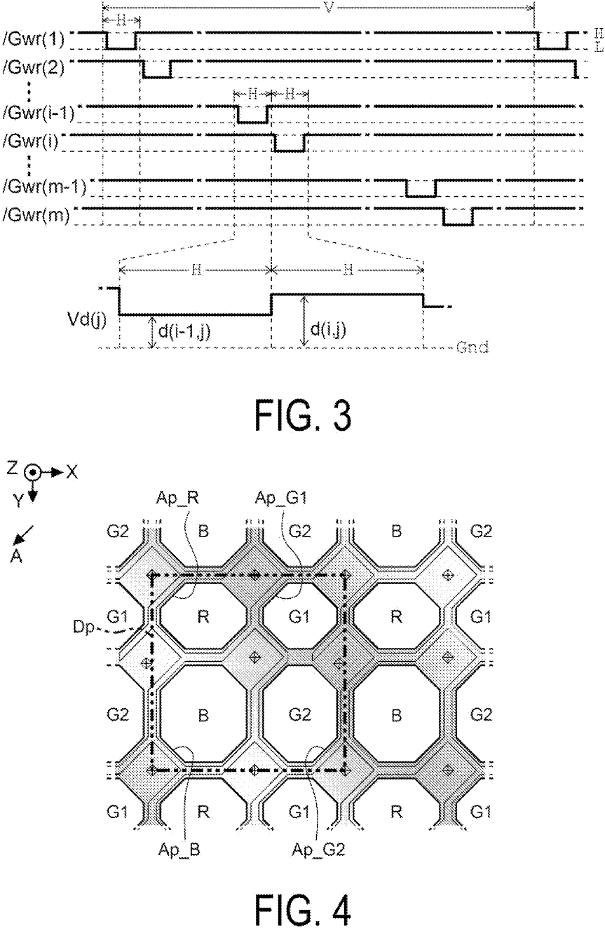

FIG. 3 is a timing chart used to explain operation of the electro-optical device 10.

In the electro-optical device 10, m rows of scanning lines 12 are scanned one row by one row in a period of a frame (V) in the order of the first, second, third, ..., and m-th rows. Specifically, as illustrated in the drawing, the scanning line drive circuit 120 sequentially brings the scanning signals /Gwr(1), /Gwr(2), ..., /Gwr(m-1), and /Gwr(m) into an L level in an exclusive manner for every horizontal scanning period (H).

Note that, in the present embodiment, periods in which adjacent scanning signals of the scanning signals /Gwr(1) to /Gwr(m) are brought into the L level are temporally separated from each other. Specifically, after the scanning signal /Gwr(i-1) changes from the L level into the H level and then a certain period elapses, the next scanning signal /Gwr(i) changes into the L level. This certain period corresponds to a horizontal blanking interval.

The period of one frame (V) as used here represents a period required to display one frame of an image designated by the video data Vid. When the length of a period of one frame (V) is equal to a vertical synchronization period and the frequency of the vertical synchronization signal contained in the synchronization signal Sync is, for example, 60 Hz, the length of a period of one frame (V) is 16.7 milliseconds corresponding to one cycle of this vertical synchronization signal. In addition, the horizontal scanning period (H) represents a time interval at which the scanning signals /Gwr(1) to /Gwr(m) are sequentially changed into the L level. In the drawing, the timing at which the horizontal scanning period (H) starts is set to almost the center of the horizontal blanking interval, for the purpose of convenience.

When a certain scanning signal of the scanning signals /Gwr(1) to /Gwr(m), that is, for example, a scanning signal /Gwr(i) to be supplied to a scanning line 12 in the i-th row is changed into the L level, the transistor 122 of a pixel portion 110 at the i-th row and j-th column is brought into the ON state in a case of the j-th column. Thus, the gate node g of the transistor 121 of this pixel circuit 110 is electrically coupled to the data line 14 in the j-th column.

Note that, in the present description, the “ON state” of a transistor represents a state in which the source node and the drain node of the transistor are electrically closed to be in a low impedance state. Furthermore, the “OFF state” of a transistor represents a state in which the source node and the drain node are electrically opened to be in a high impedance state.

In addition, in this description, the expression “electrically couple” or simply “couple” means a state where two or more elements are directly or indirectly coupled or connected to each other. The expression “not electrically couple” or simply “not couple” means a state where two or more elements are not directly or indirectly coupled or connected.

During the horizontal scanning period (H) in which the scanning signal /Gwr(i) is at the L level, the data-signal outputting circuit 50 converts gray scale levels of pixels at the i-th row and first column to the i-th row and n-th column indicated by the video data Vdata, into analog potentials Vd(1) to Vd(n), and outputs them to the data lines 14 in the first to n-th columns as data signals. In a case of the j-th column, the data-signal outputting circuit 50 converts a gray scale level d(i,j) of a pixel at the i-th row and j-th column into a potential Vd(j) that is an analog signal, and outputs it to the data line 14 in the j-th column as a data signal.

Note that, during the horizontal scanning period (H) in which a scanning signal /Gwr(i-1) in a row that is one row preceding the scanning signal /Gwr(i) is changed into the L level, the data-signal outputting circuit 50 converts a gray scale level d(i-1,j) of a pixel at the (i-1)-th row and the j-th column into a potential Vd(j) that is an analog signal, and outputs it to the data line 14 in the j-th column as a data signal.

The data signal of this potential Vd(j) is applied, through the data line 14 in the j-th column, to the gate node g of the transistor 121 of the pixel portion 110 at the i-th row and j-th column, and this potential Vd(j) is held by the capacitance element 140. Thus, this transistor 121 causes a current corresponding to a voltage across the gate node and the source node to flow through the OLED 130.

Even when the scanning signal Gwr(i) is changed into the H level and the transistor 122 is brought into the OFF state, the potential Vd(j) is held by the capacitance element 140, and hence, the current is kept flowing through the OLED 130. Thus, in the pixel portion 110 at the i-th row and j-th column, the OLED 130 keeps emitting light with brightness according to the voltage held by the capacitance element 140, that is, according to the gray scale level, until the period of one frame (V) elapses and the transistor 122 is brought into the ON again to apply a voltage of the data signal again.

Note that the pixel portion 110 at the i-th row and j-th column has been described here. In addition, in pixel portions 110 at the i-th row and columns other than the j-th column, the OLED 130 also emits light at luminance indicated by the video data Vdata.

Furthermore, as the scanning signals /Gwr(1) to /Gwr(m) are sequentially changed into the L level, the OLEDs 130 of pixel circuits 110 in rows other than the i-th row also emit light at luminance indicated by the video data Vdata.

Thus, in the electro-optical device 10, during the period of one frame (V), OLEDs 130 of all the pixel portions 110 from the pixel portion 110 at the first row and first column to the pixel portion 110 at the m-th row and n-th column emit light at luminance indicated by the video data Vdata, and an image of one frame is displayed.

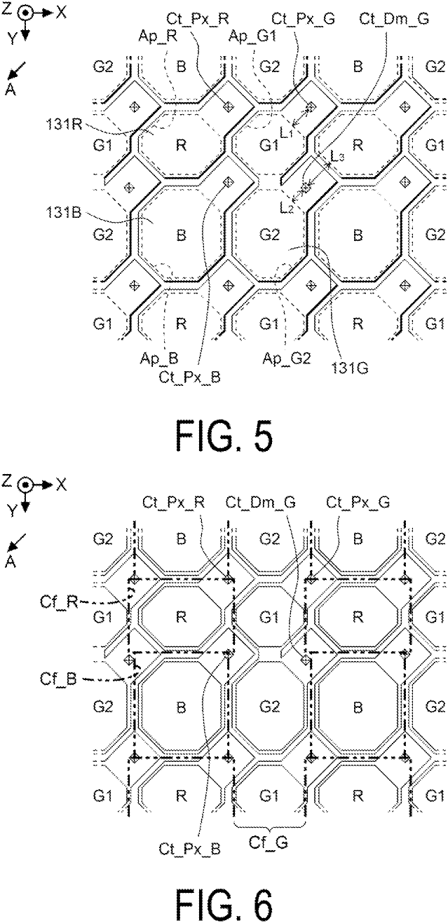

FIG. 4 is a plan view illustrating a layout of pixel portions in the display region 100 of the electro-optical device. FIG. 5 is a plan view illustrating the shape of pixel electrodes. FIG. 6 is a plan view illustrating a layout of color layers.

Specifically, FIG. 4 is a diagram illustrating, in plan view, a layout of light emitting regions R, G1, G2, and B in the display region 100.

A light emitting region R for red is a region of the pixel electrode 131R illustrated in FIG. 5 that is in contact with the light emitting layer 132. In a case of green, the light emitting region is divided into G1 and G2. The light emitting region G1, G2 is a region of the pixel electrode 131G that is in contact with the light emitting layer 132. The light emitting region B is a region of the pixel electrode 131B that is in contact with the light emitting layer 132.

The light emitting regions R, G1, G2, and B are defined by opening portions Ap_R, Ap_Gl, Ap_G2, and Ap_B, respectively. The opening portions Ap_R, Ap_Gl, Ap_G2, and Ap_B are formed through patterning of a pixel separation layer provided so as to cover the pixel electrodes 131R, 131G, and 131B as described later.

One dot of color is represented by additive color mixing of light generated from the light emitting regions R, G1, G2, and B surrounded by the frame Dp in FIG. 4.

The area of the light emitting region B is greater than the area of the light emitting region R. The sum of the area of the light emitting region G1 and the area of the light emitting region G2 is greater than the area of the light emitting region B. Of RGB, R has the highest light emitting efficiency, and hence, the light emitting region R is set to have the minimum area of the three colors. Of RGB, G has the highest visibility. In addition, in order to increase the service life, the light emitting region for G has the greatest area, that is, the sum of the area of the light emitting region G1 and the area of the light emitting region G2 is the greatest of the three colors.

In FIG. 5, the pixel electrode 131R is coupled to a lower wiring line through a pixel contact region Ct_Px_R. Furthermore, the lower wiring line is electrically coupled to a drain node of the transistor 121 in the pixel portion 110R through a plurality of components. The pixel contact region Ct_Px_R is provided so as to avoid the opening portion Ap_R as illustrated in FIGS. 5 and 6 in plan view.

The pixel electrode 131G is coupled to a lower wiring line through a pixel contact region Ct_Px_G. Furthermore, the lower wiring line is electrically coupled to a drain node of the transistor 121 in the pixel portion 110G through a plurality of components. The pixel contact region Ct_Px_G is provided in the vicinity of the light emitting region G1 of the light emitting regions G1 and G2, so as to avoid the opening portion Ap_Gl.

Note that details of the pixel contact region Ct_Px_G will be described later. In addition, the L1 represents the shortest distance from the pixel contact region Ct_Px_G to the opening portion Ap_G1.

A dummy contact region Ct_Dm_G is provided in the pixel electrode 131G. Specifically, in the present embodiment, the dummy contact region Ct_Dm_G is provided in the vicinity of the light emitting region G2 of the light emitting regions G1 and G2, so as to avoid the opening portion Ap_G2.

Here, L2 < L1 establishes where the L2 represents the shortest distance from the dummy contact region Ct_Dm_G to the opening portion Ap_G2. Furthermore, L2 < L3 establishes where the L3 represents the shortest distance from the dummy contact region Ct_Dm_G to the light emitting region R disposed obliquely right upward relative to the light emitting region G2.

Note that details of the dummy contact region Ct_Dm_G will be described later.

In FIGS. 4, 5, and 6, the direction A is a direction obtained by turning the Y direction clockwise by 45 degrees, and is a direction parallel to a direction connecting two points used at the time of identifying the distances L1, L2, and L3.

The pixel electrode 131B is electrically coupled to the drain node of the transistor 121 in the pixel portion 110B through the pixel contact region Ct_Px_B. The pixel contact region Ct_Px_B is provided so as to avoid the opening portion Ap_B in plan view.

As illustrated in FIG. 6, a red color layer Cf_R is provided at the light emitting region R. A green color layer Cf_G is provided at the light emitting regions G1 and G2. A blue color layer Cf_B is provided at the light emitting region B2.

The pixel contact regions Ct_Px_R, Ct_Px_G, and Ct_Px_B are provided at boundaries of the color layers Cf_R, Cf_G and Cf_B in plan view. The dummy contact region Ct_Dm_G is provided at a position that overlaps with the color layer Cf_G in plan view.

The dummy contact region Ct_Dm_G is surrounded by four regions of the light emitting regions R, G1, G2, and B in plan view. In addition, as viewed in the direction A, the light emitting region R, the dummy contact region Ct_Dm_G, and the light emitting region G2 are arrayed in this order. As viewed in a direction obtained by turning the direction A clockwise by 90 degrees, the light emitting region B, the dummy contact region Ct_Dm_G, and the light emitting region G1 are arrayed in this order.

Next, description will be sequentially made of structures of the pixel contact region Ct_Px_R of the pixel portion 110R, the pixel contact region Ct_Px_G of the pixel portion 110G, the pixel contact region Ct_Px_B of the pixel portion 110B, and the dummy contact region Ct_Dm_G of the pixel portion 110G.

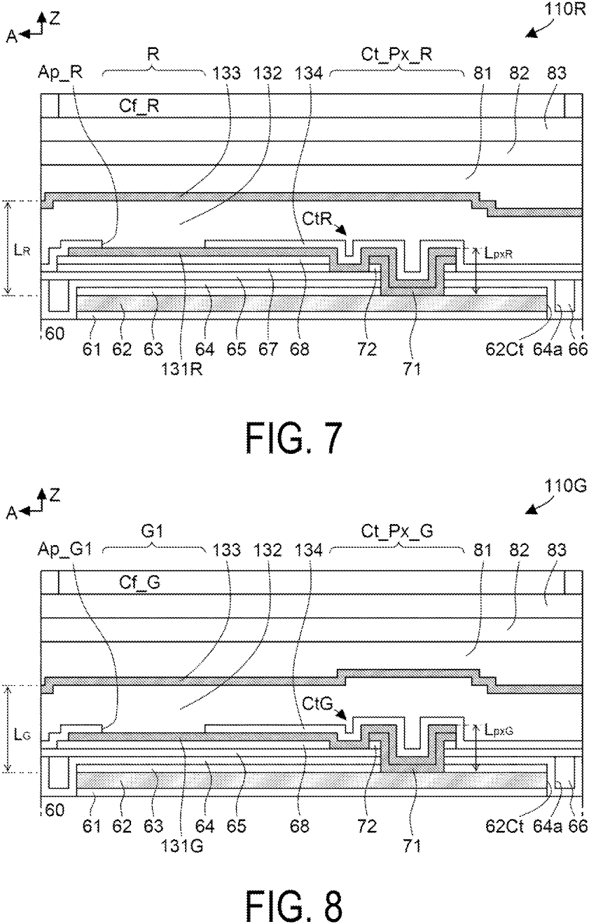

FIG. 7 is a cross-sectional view illustrating the main components including the light emitting region R and the pixel contact region Ct_Px_R in the pixel portion 110R. Note that FIG. 7 is a cross-sectional view obtained by taking, along the direction A, a region including the light emitting region R and the pixel contact region Ct_Px_R in FIG. 5.

A contact electrode 61 is electrically coupled, through a contact hole, to a circuit layer formed at a substrate 60. Note that the circuit layer disposed at a lower layer includes the scanning line 12, the data line 14, and the transistors 121 and 122.

A reflection layer 62 is stacked at the contact electrode 61, and is configured to reflect, in the Z direction, light entering from a direction opposite to the Z direction. For the reflection layer 62, a conductive layer is used, and the conductive layer is obtained, for example, by stacking a film of an alloy (AlCu) of aluminum, copper, and the like at a titanium (Ti) film. The contact electrode 61 and the reflection layer 62 are formed in an island manner in plan view separately for each of the pixel portions 110R, 110G, and 110B. Note that a gap 62Ct is generated due to island formation.

A reflection enhancing layer 63 is a layer used to enhance a reflection property provided by the reflection layer 62. The reflection enhancing layer 63 has an insulation property and optical transparency and is provided so as to cover the reflection layer 62. For example, silicon oxide is used for the reflection enhancing layer 63.

A first insulating layer 64 is provided along the gap 62Ct so as to cover the reflection enhancing layer 63. Thus, the first insulating layer 64 includes a recessed portion 64a at or around the gap 62Ct. A filling insulating layer 66 is provided so as to fill the recessed portion 64a. The second insulating layer 65 is stacked at the first insulating layer 64 and the filling insulating layer 66. For example, silicon nitride (SiN) is used for the first insulating layer 64 and the second insulating layer 65. In addition, for example, a silicon oxide is used for the filling insulating layer 66.

A protection layer 72 is an insulating film stacked at the second insulating layer 65, and silicon oxide is used, for example.

The reflection enhancing layer 63, the first insulating layer 64, the second insulating layer 65, and the protection layer 72 are opened at the pixel contact region Ct_Px_R.

A relay layer 71 is a conductive layer stacked along this opening and at the reflection layer 62 and the protection layer 72. The relay layer 71 includes a recessed portion provided along this opening. For example, titanium nitride (TiN) is used for the relay layer 71.

A first optical adjusting layer 67 and a second optical adjusting layer 68 are insulating layers each configured to have optical transparency and used to adjust the optical distance at the optical resonator. For example, silicon oxide is used for the first optical adjusting layer 67 and the second optical adjusting layer 68. The first optical adjusting layer 67 and the second optical adjusting layer 68 are opened at the region CtR of the pixel contact region Ct_Px_R.

The pixel electrode 131R is a conductive layer having optical transparency. The pixel electrode 131R is stacked at the second optical adjusting layer 68 or the relay layer 71, and is stacked at the second insulating layer 65 in the region CtR where the first optical adjusting layer 67 and the second optical adjusting layer 68 are opened. The pixel electrode 131R is formed in a manner illustrated in FIG. 5 in plan view. Since the pixel electrode 131R is stacked along the opening in the region CtR, the pixel electrode 131R includes a recessed portion so as to correspond to this region CtR. For example, indium tin oxide (ITO) is used for the pixel electrode 131R.

The pixel separation layer 134 is stacked at the second optical adjusting layer 68, the second insulating layer 65, or the pixel electrode 131R, and is an insulating film provided so as to cover a peripheral edge portion of the pixel electrode 131R. In a case of the pixel portion 110R, the pixel separation layer 134 includes an opening portion Ap_R having the shape illustrated in FIG. 4 in plan view. For example, silicon oxide is used as the pixel separation layer 134.

The light emitting layer 132 is stacked at the pixel electrode 131R or the pixel separation layer 134. Although no particular illustration is given, the light emitting layer 132 includes a positive-hole injection layer, a hole transport layer, an organic light emitting layer, and an electron-transporting layer, and is common to all the pixels for R, G, and B.

The common electrode 133 is a conductive layer having optical transparency and a reflective property. The common electrode 133 is provided so as to cover the light emitting layer 132, and is common to all the pixel portions of the pixel portions 110R, 110G, and 110B. For example, an alloy or the like of Mg and Ag is used for the common electrode 133.

The light emitting layer 132 is supplied with a positive hole from a region of the pixel electrode 131R that is not covered with the pixel separation layer 134, that is, a region that is in contact with the pixel electrode 131R and is defined by the opening portion Ap_R, and emits white light.

An optical resonator comprised of the reflection layer 62 and the common electrode 133 is formed at a portion of the pixel portion 110R that corresponds to the light emitting region R. An optical distance LR between the reflection layer 62 and the common electrode 133 is adjusted with the film thicknesses of the first optical adjusting layer 67 and the second optical adjusting layer 68.

Note that, in a strict sense, the optical distance represents a value obtained by multiplying a distance between the reflection layer 62 and the common electrode 133 by the refractive index of a medium between the reflection layer 62 and the common electrode 133. However, the optical distance here is illustrated simply as a physical distance.

In a portion corresponding to the light emitting region R, white light emitted from the light emitting layer 132 is repeatedly reflected between the reflection layer 62 and the common electrode 133. This increases the intensity of light having a wavelength corresponding to the optical distance LR. In the present embodiment, the intensity of light having a wavelength of 610 nm is enhanced through the pixel portion 110R, by way of example. This enhanced light passes through the common electrode 133 and the color layer Cf_R, and is outputted as red light in the Z direction.

In this manner, red light is outputted in the Z direction from the light emitting region R in plan view.

A first encapsulating layer 81 is an insulating layer having optical transparency, and is provided so as to cover the common electrode 133.

A flattening layer 82 is an insulating layer having optical transparency, and is provided so as to cover the first encapsulating layer 81 to make the observation surface flattened without any step. For example, an organic material such as epoxy resin or the like is used for the flattening layer 82.

A second encapsulating layer 83 is an insulating layer having optical transparency, and is provided so as to cover the flattening layer 82. The first encapsulating layer 81 and the second encapsulating layer 83 are provided to prevent moisture, oxygen, or the like from entering the light emitting layer 132. For example, silicon oxynitride (SiON) is used for the first encapsulating layer 81 and the second encapsulating layer 83.

At the pixel portion 110R, the color layer Cf_R is provided so as to cover the second encapsulating layer 83 in plan view as illustrated in FIG. 6. The color layer Cf_R is provided with photosensitive resin containing pigment that allows red light to pass through, through patterning using a photolithography technique.

Note that the color layer Cf_R is provided at the pixel portion 110R. The green color layer Cf_G is provided at the pixel portion 110G. The blue color layer Cf_B is provided at the pixel portion 110B. In addition, although a filling layer, a protection glass, or the like is provided at the color layers Cf_R, Cf_G, and Cf_B, these components are not illustrated as they are not important components in this case.

FIG. 8 is a cross-sectional view illustrating the main components including the light emitting region G1 and the pixel contact region Ct_Px_G in the pixel portion 110G. Note that FIG. 8 is a cross-sectional view obtained by taking, along the direction A, a region including the light emitting region G1 and the pixel contact region Ct_Px_G in FIG. 5.

A difference from the pixel portion 110R in FIG. 7 lies in that the first optical adjusting layer 67 that is provided in the pixel portion 110R is not provided in the pixel portion 110G.

Specifically, in a portion corresponding to the light emitting region R, the first optical adjusting layer 67 and the second optical adjusting layer 68 are provided between the reflection layer 62 and the pixel electrode 131R, whereas, in a portion corresponding to the light emitting region G1, the first optical adjusting layer 67 is not provided between the reflection layer 62 and the pixel electrode 131G.

Thus, the optical distance LG between the reflection layer 62 and the common electrode 133 in the portion corresponding to the light emitting region G1 is shorter than the optical distance LR in the portion corresponding to the light emitting region R, by the length of the first optical adjusting layer 67 that does not exist.

The pixel electrode 131G is stacked at the second optical adjusting layer 68 or the relay layer 71, and is stacked at the second insulating layer 65 in a region CtG. The pixel electrode 131G is formed in a manner illustrated in FIG. 5 in plan view. The pixel electrode 131G is stacked along the opening of the region CtG, and hence, has a recessed portion corresponding to the region CtG.

In a portion corresponding to the light emitting region G1, white light emitted from the light emitting layer 132 is repeatedly reflected between the reflection layer 62 and the common electrode 133. This increases the intensity of light having a wavelength corresponding to the optical distance LG.

In the present embodiment, the intensity of light having a wavelength of 540 nm is enhanced through the pixel portion 110G, by way of example. This enhanced light passes through the common electrode 133 and the color layer Cf_G, and is outputted as green light in the Z direction.

In this manner, green light is outputted in the Z direction from the light emitting region G1 in plan view.

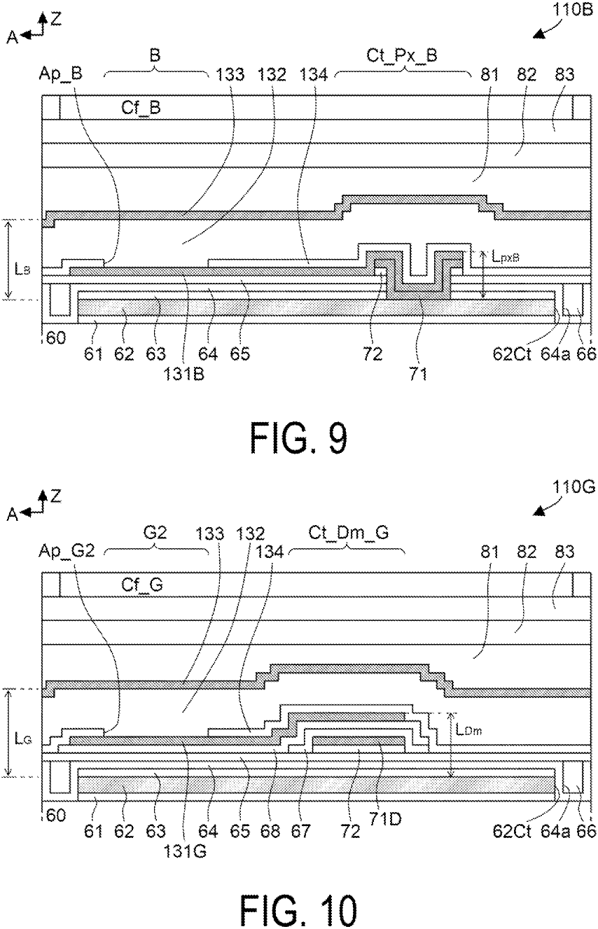

FIG. 9 is a cross-sectional view illustrating the main components including the light emitting region B and the pixel contact region Ct_Px_B in the pixel portion 110B. Note that FIG. 9 is a cross-sectional view obtained by taking, along the direction A, a region including the light emitting region B and the pixel contact region Ct_Px_B in FIG. 5.

A difference from the pixel portion 110G in FIG. 8 lies in that the second optical adjusting layer 68 that is provided in the pixel portion 110G is not provided in the pixel portion 110B. Thus, the optical distance LB between the reflection layer 62 and the common electrode 133 in the portion of the pixel portion 110B that corresponds to the light emitting region B is shorter by the length of the second optical adjusting layer 68 that does not exist, than the optical distance LG in the portion corresponding to the light emitting region G1.

Neither the first optical adjusting layer 67 nor the second optical adjusting layer 68 exists in the pixel electrode 131B. Hence, neither the opening portion at the region CtR in the pixel portion 110R nor the opening portion at the region CtG in the pixel portion 110G is provided. Thus, the pixel electrode 131B is stacked at the relay layer 71 in the pixel contact region Ct_Px_B, and is stacked at the second insulating layer 65 in the other region.

In a portion corresponding to the light emitting region B, white light emitted from the light emitting layer 132 is repeatedly reflected between the reflection layer 62 and the common electrode 133. This increases the intensity of light having a wavelength corresponding to the optical distance LB. In the present embodiment, the intensity of light having a wavelength of 470 nm is enhanced through the pixel portion 110B, by way of example. This enhanced light passes through the common electrode 133 and the color layer Cf_B, and is outputted as blue light in the Z direction.

In this manner, blue light is outputted in the Z direction from the light emitting region B in plan view.

As can be understood from FIGS. 7, 8, and 9, a distance LpxR, a distance LpxG, and a distance LpxB are substantially equal to each other. The distance LpxR is a distance from the reflection layer 62 to the pixel electrode 131R in the pixel contact region Ct_Px_R. The distance LpxG is a distance from the reflection layer 62 to the pixel electrode 131G in the pixel contact region Ct_Px_G. The distance LpxB is a distance from the reflection layer 62 to the pixel electrode 131B in the pixel contact region Ct_Px_B.

That is, in the present embodiment, in these pixel contact regions, the distances to the pixel electrodes 131R, 131G, 131B are substantially equal to each other with the reflection layer 62 being the reference, and the heights of the pixel contact regions Ct_Px_R, Ct_Px_G, Ct_Px_B are substantially aligned with each other. Thus, first, in the present embodiment, it is possible to prevent abnormal light emission due to a difference in height between the pixel contact regions Ct_Px_R, Ct_Px_G, and Ct_Px_B.

FIG. 10 is a cross-sectional view illustrating a portion of the pixel portion 110G that includes the dummy contact region Ct_Dm_G. Note that FIG. 10 is a cross-sectional view obtained by taking, along the direction A, a region including the light emitting region G2 and the dummy contact region Ct_Dm_G in FIG. 5.

In FIG. 10, the light emitting region G2 is substantially equal to the light emitting region G1 in FIG. 8, and the optical distance between the reflection layer 62 and the common electrode 133 is substantially equal to the LG.

In the dummy contact region Ct_Dm_G, the protection layer 72 and a dummy relay layer 71D are provided, in this order, at a surface of the second insulating layer 65 at the Z direction. The dummy relay layer 71D is formed through patterning of the same layer as the relay layer 71. However, the dummy relay layer 71D is independent of the relay layer 71, and is not electrically coupled to the relay layer 71.

In the dummy contact region Ct_Dm_G, the first optical adjusting layer 67 is provided so as to cover the protection layer 72 and the dummy relay layer 71D. However, the first optical adjusting layer 67 is not provided at a portion corresponding to the light emitting region G2.

The second optical adjusting layer 68 is provided so as to cover the second insulating layer 65 in a portion corresponding to the light emitting region G2, and is provided so as to cover the first optical adjusting layer 67 in the dummy contact region Ct_Dm_G.

In the light emitting region G2 and the dummy contact region Ct_Dm_G, the pixel electrode 131G is stacked at the second optical adjusting layer 68, and is formed so as to have a shape illustrated in FIG. 5 in plan view.

In the dummy contact region Ct_Dm_G, the first optical adjusting layer 67 and the second optical adjusting layer 68 exist between the pixel electrode 131G and the dummy relay layer 71D, and the protection layer 72, the second insulating layer 65, and the like exist between the dummy relay layer 71D and the reflection layer 62.

Thus, in the present embodiment, the pixel electrode 131G and the dummy relay layer 71D are not electrically coupled to each other, and the dummy relay layer 71D and the reflection layer 62 are not electrically coupled to each other.

In the present embodiment, the term “dummy contact region” is used because the pixel electrode 131G is in a state of being not electrically coupled to the reflection layer 62 (the drain node of the transistor 121) in the dummy contact region Ct_Dm_G, and does not contribute to electrical coupling.

In the light emitting region G2 and the dummy contact region Ct_Dm_G, the pixel separation layer 134 is stacked at the second optical adjusting layer 68, the second insulating layer 65, or the pixel electrode 131G. The pixel separation layer 134 includes an opening portion Ap_G2 having the shape illustrated in FIG. 4 in plan view. Thus, the green light is also outputted in the Z direction from the light emitting region G2 in plan view, in addition to the light emitting region G1.

In this manner, in the dummy contact region Ct_Dm_G in the present embodiment, the reflection enhancing layer 63, the first insulating layer 64, the second insulating layer 65, the protection layer 72, the dummy relay layer 71D, the first optical adjusting layer 67, and the second optical adjusting layer 68 are provided sequentially from the reflection layer 62 up to the pixel electrode 131G.

In the pixel contact regions Ct_Px_R, Ct_Px_Gl, and Ct_Px_B, the distance from the reflection layer 62 up to the pixel electrode 131 is aligned at the pixel portion 110R, 110G, 110B. Specifically, in the pixel contact regions Ct_Px_R, Ct_Px_Gl, Ct_Px_B, the reflection enhancing layer 63, the first insulating layer 64, the second insulating layer 65, the protection layer 72, and the relay layer 71 are provided sequentially from the reflection layer 62 up to the pixel electrode 131.

In other words, in the pixel contact regions Ct_Px_R, Ct_Px_Gl, and Ct_Px_B, neither the first optical adjusting layer 67 nor the second optical adjusting layer 68 is provided, as compared with the dummy contact region Ct_Dm_G. Thus, in the dummy contact region Ct_Dm_G, the distance LDm from the reflection layer 62 up to the pixel electrode 131G is longer than the distance LpxR, LpxG, LpxB in the pixel contact region Ct_Px_R, Ct_Px_Gl, Ct_Px_B. That is, in the pixel portions 110R, 110G, and 110B, the distance up to the pixel electrode 131 in the Z direction with the reflection layer 62 being the reference is the longest (the thickest) at the dummy contact region Ct_Dm_G.

The first encapsulating layer 81 is provided so as to cover the common electrode 133. The flattening layer 82 provided so as to cover the first encapsulating layer 81 is formed, for example, through screen printing. Screen printing is printing using a “screen mesh” woven with synthetic fiber or metal fiber, and a squeegee is moved to pass organic materials such as epoxy resin through screen mesh, thereby to perform printing so as to cover the first encapsulating layer 81. During screen printing, the intersection of mesh presses the first encapsulating layer 81 in association with movement of the squeegee. At the time of the pressing, there may be a case where force does not uniformly act in the display region 100, and some portions are more pressed than other regions. In addition, the step of manufacturing the electro-optical device 10 not only include the screen printing, and some other force may act in the display region 100 to press a portion of the regions.

At the pressed region, a locally thin portion is created in the light emitting layer 132. The locally thin portion of the the light emitting layer 132 has a low resistance value, and a small electric current is more likely to flow. When a small electric current flows, light of red that has high efficiency tends to be emitted. Note that this red light is light having a wavelength region that resonates with the optical resonator at the optical distance LR.

In order to avoid this phenomenon, it is possible to deal with this by increasing the thickness of the flattening layer 82. However, this leads to an increase in the distance from the light emitting layer 132 to the color layer Cf_R, Cf_G, Cf_B, which causes a problem of decreasing the visual field angle.

In the present embodiment, when a portion of the display region 100 is pressed, the dummy contact region Ct_Dm_G works as a stopper to suppress this pressing. Thus, it is possible to suppress the light emitting layer 132 being locally thin in the light emitting regions R, G1, G2, and B.

In addition, a portion of the light emitting layer 132 that has a thickness reduced due to the pressing is at or around the dummy contact region Ct_Dm_G. A portion of the light emitting layer 132 of which thickness reduces tends to emit light in red as described above. When viewed in plan view, the dummy contact region Ct_Dm_G is close to the light emitting region G2, is spaced apart from the color layer Cf_R, and is included in the color layer Cf_G. Thus, even if red light is emitted due to the thickness of the light emitting layer 132 being reduced at and around the dummy contact region Ct_Dm_G, this red light is blocked by the color layer Cf_G, and hence, this red light is not visually recognized by an observer. Thus, with the present embodiment, it is possible to suppress a deterioration in the display quality due to local pressing on the display region 100.

Note that the light emitting element 130R includes the pixel electrode 131R, the light emitting layer 132, and the common electrode 133 from the electrical viewpoint, whereas, from the structural viewpoint, the light emitting element 130R includes the pixel contact region Ct_Px_R and the relay layer 71 configured to supply the pixel electrode 131R with a current from the transistor 121, in addition to the light emitting region R.

The light emitting element 130G includes the pixel electrode 131G, the light emitting layer 132, and the common electrode 133 from the electrical viewpoint, whereas, from the structural viewpoint, the light emitting element 130G includes the pixel contact region Ct_Px_G, the dummy contact region Ct_Dm_G, the dummy relay layer 71D, and the relay layer 71 configured to supply the pixel electrode 131G with a current from the transistor 121, in addition to the light emitting regions G1 and G2.

The light emitting element 130B includes the pixel electrode 131G, the light emitting layer 132, and the common electrode 133 from the electrical viewpoint, whereas, from the structural viewpoint, the light emitting element 130B includes the pixel contact region Ct_Px_B and the relay layer 71 configured to supply the pixel electrode 131B with a current from the transistor 121, in addition to the light emitting region B.

Next, the electro-optical device 10 according to a second embodiment will be described. In the second embodiment, the structure of the dummy contact region Ct_Dm_G is modified, and except for the dummy contact region Ct_Dm_G, the second embodiment is the same as the first embodiment. Thus, in the second embodiment, explanation of portions other than the dummy contact region Ct_Dm_G will not be given. In addition, the same reference characters are attached to the same components as those in the first embodiment, and explanation thereof will not be made as appropriate.

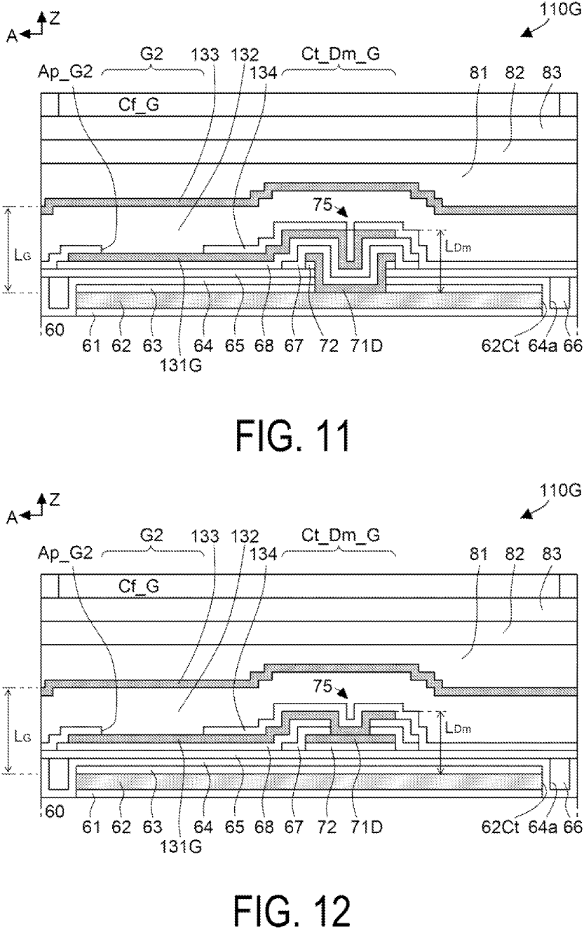

FIG. 11 is a partial cross-sectional view illustrating a region including the dummy contact region Ct_Dm_G. Note that, as in FIG. 10, FIG. 11 is a cross-sectional view obtained by taking, along the direction A, a region including the light emitting region G2 and the dummy contact region Ct_Dm_G in FIG. 5.

In the second embodiment, the reflection enhancing layer 63, the first insulating layer 64, the second insulating layer 65, and the protection layer 72 are opened at the dummy contact region Ct_Dm_G, as illustrated in FIG. 11.

Thus, the dummy relay layer 71D is electrically coupled to the reflection layer 62 at the dummy contact region Ct_Dm_G. The first optical adjusting layer 67 is provided so as to cover the dummy relay layer 71D, and is not provided at the light emitting region G2. The second optical adjusting layer 68 is provided so as to cover the first optical adjusting layer 67 at the dummy contact region Ct_Dm_G and the light emitting region G2.

In the light emitting region G2 and the dummy contact region Ct_Dm_G, the pixel electrode 131G is stacked at the second optical adjusting layer 68, and is formed so as to have a shape illustrated in FIG. 5 in plan view.

The relay layer 71, the first optical adjusting layer 67, the second optical adjusting layer 68, and the pixel electrode 131G are provided along the opening portions of the reflection enhancing layer 63, the first insulating layer 64, the second insulating layer 65, and the protection layer 72 in the dummy contact region Ct_Dm_G.

Thus, in the dummy contact region Ct_Dm_G, the relay layer 71, the first optical adjusting layer 67, the second optical adjusting layer 68, and the pixel electrode 131G have a recessed portion 75 corresponding to the opening portion.

In this manner, in the second embodiment, the pixel electrode 131G and the dummy relay layer 71D are in a state of being not electrically coupled to each other, and the dummy relay layer 71D and the reflection layer 62 are in a state of being electrically coupled to each other.

With the second embodiment, it is possible to suppress a deterioration in the display quality due to local pressing on the display region 100, as with the first embodiment.

In addition, in the second embodiment, the recessed portion 75 is provided at the dummy contact region Ct_Dm_G, as compared with the first embodiment. Due to this recessed portion 75, the covering power of the light emitting layer 132 deteriorates around this recessed portion 75, which results in a local reduction in the thickness of the light emitting layer 132. As the thickness of the light emitting layer 132 reduces, the resistance of the light emitting layer 132 reduces, which makes it more likely to cause abnormal light emission. The abnormal light emission due to the reduction in the thickness of the light emitting layer 132 results from a reduction in the resistance of the light emitting layer 132. Thus, light is emitted in red having the high efficiency in emitting light.

However, the dummy contact region Ct_Dm_G is provided at a position spaced apart from the light emitting regions R, G1, G2, and B in plan view and overlapping with the color layer Cf_G. Thus, the abnormal light emitted in red generated at and around the dummy contact region Ct_Dm_G is blocked by the green color layer Cf_G and is less likely to be visually recognized. This makes it possible to suppress a deterioration in the display quality. In other words, in the second embodiment, the recessed portion 75 is used to cause the abnormal light emission, which is less likely to be visually recognized, to be generated so as to concentrate on the portion where the thickness of the light emitting layer 132 is locally reduced. This makes it possible to reduce the adverse influence in the light emitting region R, G1, G2, and B.

In addition, in the second embodiment, a step at the dummy contact region Ct_Dm_G not only deteriorates the light emitting layer 132 but also deteriorates the covering power of the first encapsulating layer 81. When the covering power of the first encapsulating layer 81 deteriorates, the shielding property against moisture deteriorates. However, it is possible to easily find the mixing of foreign substances (contaminant) into the second encapsulating layer 83 stacked at the flattening layer 82.

Note that, in a first modification example and a second modification example that will be described below, it is also possible to form the recessed portion 75 in the dummy contact region Ct_Dm_G to make a step.

FIG. 12 is a partial cross-sectional view illustrating a region including the dummy contact region Ct_Dm_G according to a first modification example.

As illustrated in FIG. 12, in the first modification example, the first optical adjusting layer 67 and the second optical adjusting layer 68 are opened at the dummy contact region Ct_Dm_G, as compared with FIG. 10. Thus, the pixel electrode 131G is electrically coupled to the dummy relay layer 71D at the dummy contact region Ct_Dm_G.

In the first modification example, the reflection enhancing layer 63, the first insulating layer 64, the second insulating layer 65, and the protection layer 72 are provided between the reflection layer 62 and the dummy relay layer 71D.

Thus, in the first modification example, the pixel electrode 131G is electrically coupled to the dummy relay layer 71D at the dummy contact region Ct_Dm_G, and is not electrically coupled to the dummy relay layer 71D or the reflection layer 62.

With the first modification example, it is possible to suppress a deterioration in display quality due to local pressing on the display region 100, as with the first embodiment. In addition, with the first embodiment, due to the step at the dummy contact region Ct_Dm_G, it is possible to easily find the mixing of foreign substances into the second encapsulating layer 83, as with the second embodiment.

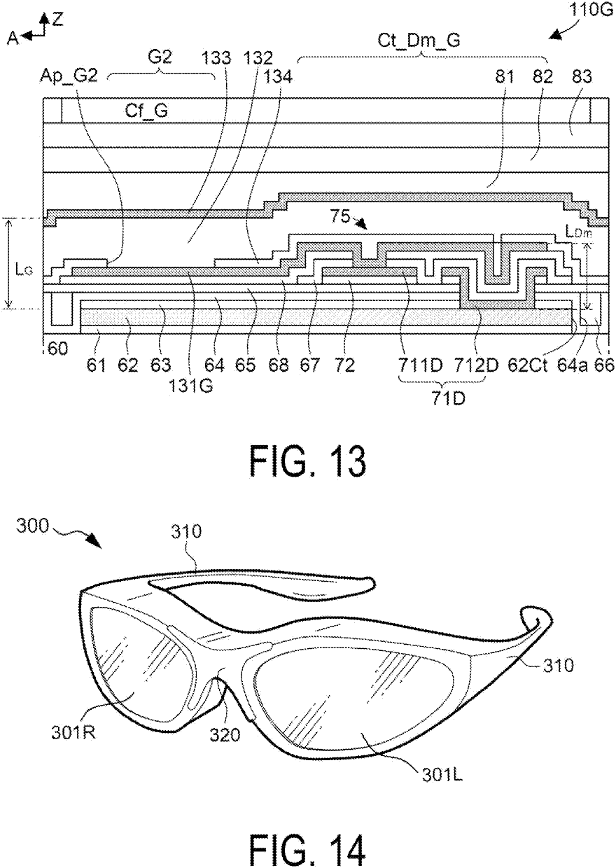

FIG. 13 is a partial cross-sectional view illustrating a region including the dummy contact region Ct_Dm_G in the second modification example.

As illustrated in FIG. 13, the second modification example is configured such that the dummy contact region according to the second embodiment and the dummy contact region according to the first modification example are provided alongside in the dummy contact region Ct_Dm_G.

In the second modification example, the dummy relay layer 71D includes a first dummy relay layer 711D and a second dummy relay layer 712D. Of these layers, the first dummy relay layer 711D corresponds to the dummy relay layer 71D at the dummy contact region according to the first modification example, and is electrically coupled to the pixel electrode 131. In addition, the second dummy relay layer 712D corresponds to the dummy relay layer 71D according to the second embodiment, and is electrically coupled to the reflection layer 62. The first dummy relay layer 711D and the second dummy relay layer 712D are formed through patterning of a conductive layer that is the same as the relay layer 71, and are not electrically coupled to each other.

In the second modification example, a region containing the step in the dummy contact region Ct_Dm_G expands, as compared with the second embodiment or the first modification example, and hence, it is possible to more easily find the mixing of foreign substances into the second encapsulating layer 83.

### Electronic Device

Next, description will be made of an electronic device to which the electro-optical device 10 according to the embodiments or the like is applied. The electro-optical device 10 is suitable for applications in which pixel size is small and high definition display is performed. Thus, description will be made by giving a head-mounted display as an example of the electronic device.

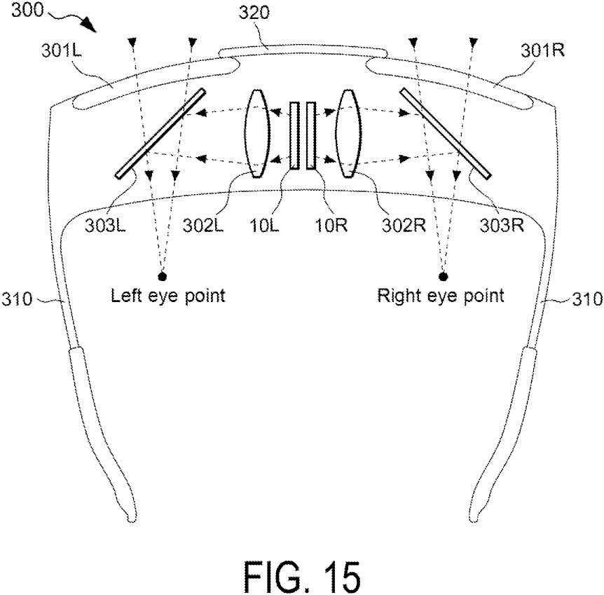

FIG. 14 is a diagram illustrating the external appearance of the head-mounted display. FIG. 15 is a diagram illustrating the optical configuration thereof.

First, as illustrated in FIG. 14, the head-mounted display 300 includes a temple 310, a bridge 320, and lenses 301L and 301R as with typical eyeglasses in terms of the external appearance. In addition, as illustrated in FIG. 15, the head-mounted display 300 includes a left-eye electro-optical device 10L and a right-eye electro-optical device 10R provided in the vicinity of the bridge 320 and at the back (at the lower side in the drawing) of the lenses 301L and 301R.

An image display surface of the electro-optical device 10L is disposed so as to be at the left in FIG. 15. With this configuration, the display image by the electro-optical device 10L exits through an optical lens 302L in the direction of nine o’clock in the drawing. A half mirror 303L reflects the display image by the electro-optical device 10L toward the direction of six o’clock while allowing light entering from the direction of 12 o’clock to pass through. An image display surface of the electro-optical device 10R is disposed so as to be at the right that is opposite to the electro-optical device 10L. With this configuration, the display image by the electro-optical device 10R exits through an optical lens 302R in the direction of three o’clock in the drawing. A half mirror 303R reflects the display image by the electro-optical device 10R toward the direction of six o’clock while allowing light entering from the direction of 12 o’clock to pass through.

With this configuration, a wearer of the head-mounted display 300 can observe the display images by the electro-optical devices 10L and 10R in a see-through state in which the display images by the electro-optical devices 10L and 10R overlap with the outside.

In addition, in this head-mounted display 300, of images for both eyes with parallax, an image for a left eye is displayed by the electro-optical device 10L, and an image for a right eye is displayed by the electro-optical device 10R. This makes it possible to cause a wearer to sense the displayed images as an image displayed having a depth or a three dimensional effect.

In addition to the head-mounted display 300, it is possible to apply an electronic device including the electro-optical device 10 to an electronic viewing finder in a video camera, a lens-exchangeable digital camera, or the like, a personal digital assistant, a display unit of a wrist watch, a light bulb of a projection-type projector, or the like.

### Note

On the basis of the description above, it is possible to obtain preferred aspects of the present disclosure, for example, in the following manner. Note that, in the following description, in order to facilitate understanding of each aspect, the reference characters attached in the drawings are also written in blankets for the purpose of convenience. However, this does not intend to limit the present disclosure to the aspects illustrated in the drawings.

### Note 1

An electro-optical device (10) according to one aspect (first aspect) includes: a substrate (60); a first light emitting element (130G) including a common electrode (133), a first pixel electrode (131G), and a light emitting layer (132); a first reflection layer (62) provided between the substrate (60) and the first pixel electrode (131G); and the first relay layer (71) configured to electrically couple the first reflection layer (62) and the first pixel electrode (131G), in which, in a region where the first pixel electrode (131G) and the light emitting layer (132) overlap with each other, the first light emitting element (130G) includes in plan view: a first light emitting region (G1) where the first pixel electrode (131G) and the light emitting layer (132) are in contact with each other; a first pixel contact region (Ct_Px_G) where the first pixel electrode (131G) and the first relay layer (71) overlap with each other in plan view; and a non-coupling region (Ct_Dm_G) disposed at an outside of the first light emitting region (G1) in plan view and differing from the first pixel contact region (Ct_Px_G), in a direction of a thickness of the substrate (60), a distance between the first reflection layer (62) and the first pixel electrode (131G) in the non-coupling region (Ct_Dm_G) is longer than a distance between the first reflection layer (62) and the first pixel electrode (131G) in the first pixel contact region (Ct_Px_G), and a first color layer (Cf_G) is provided so as to overlap with the non-coupling region (Ct_Dm_G) in plan view and is configured to block light emitted from the non-coupling region (Ct_Dm_G).

In the first aspect, when a portion of the electro-optical device (10) is pressed, the non-coupling region (Ct_Dm_G) works as a stopper to suppress this pressing. In addition, even when the thickness of the light emitting layer 132 reduces due to the pressing, the thickness reduced portion is limited to the vicinity of the non-coupling region (Ct_Dm_G). With the first aspect, even when abnormal light emission occurs at and around the non-coupling region (Ct_Dm_G), the abnormal light emission is blocked by the color layer (Cf_G). Thus, with the first aspect, the abnormal light emission is prevented from being visually recognized by an observer, which makes it possible to suppress a deterioration in the display quality.

Note that the pixel electrode 131G serves as one example of the first pixel electrode. The OLED 130G serves as one example of the first light emitting element. The reflection layer 62 at the pixel portion 110 for G serves as one example of the first reflection layer. The relay layer 71 at the pixel portion 110 for G serves as one example of the first relay layer. The color layer Cf_G serves as one example of the first color layer. In addition, the dummy contact region (Ct_Dm_G) serves as one example of the non-coupling region.

### Note 2

An electro-optical device (10) according to a specific aspect (second aspect) of the first aspect includes: a dummy relay layer (71D) provided between the first reflection layer (62) and the first pixel electrode (131G) and not electrically coupled to at least one of the first reflection layer (62) and the first pixel electrode (131G), and the non-coupling region (Ct_Dm_G) is a region where the first pixel electrode (131G), the dummy relay layer (71D), the light emitting layer (132), and the common electrode (133) overlap in plan view.

Note that, in the second aspect, there is a case where the dummy relay layer (71D) and at least one of the first reflection layer (62) and the first pixel electrode (131G) are not electrically coupled to each other. For such an aspect, the following third to fifth aspects can be considered.

### Note 3

In an electro-optical device (10) according to a specific aspect (third aspect) of the second aspect, the dummy relay layer (71D) is not electrically coupled to the first reflection layer (62), and the first pixel electrode (131G) and the first pixel electrode are not electrically coupled to each other.

### Note 4

In an electro-optical device (10) according to a specific aspect (fourth aspect) of the second aspect, the dummy relay layer (71D) is electrically coupled to the first reflection layer (62), and is not electrically coupled to the first pixel electrode (131G).

### Note 5

In an electro-optical device (10) according to a specific aspect (fifth aspect) of the second aspect, the dummy relay layer (71D) is not electrically coupled to the first reflection layer (62), and is electrically coupled to the first pixel electrode (131G).

### Note 6

In an electro-optical device (10) according to a specific aspect (sixth aspect) of the second aspect, the dummy relay layer (71D) includes a first dummy relay layer (711D) electrically coupled to the first pixel electrode (131G), and a second dummy relay layer (712D) electrically coupled to the first reflection layer (62), and the first dummy relay layer (711D) and the second dummy relay layer (712D) are not electrically coupled to each other.

### Note 7

An electro-optical device (10) according to a specific aspect (seventh aspect) of the first aspect includes: a second light emitting element (130B) including the common electrode (132), a second pixel electrode (131B), and the light emitting layer (132); a second reflection layer (62) provided between the substrate (60) and the second pixel electrode (131B); and a second relay layer (71) configured to electrically couple the second reflection layer (62) and the second pixel electrode (131B), in which, in a region where the second pixel electrode (131B) and the light emitting layer (132) overlap with each other in plan view, the second light emitting element (130B) includes: a second light emitting region (B) where the second pixel electrode (131B) and the light emitting layer (132) are in contact with each other; and a second pixel contact region (Ct_Px_B) where the second pixel electrode (131B) and the second relay layer (71) overlap with each other in plan view, in a direction of a thickness of the substrate (60), a distance between the first reflection layer (62) and the first pixel electrode (131G) in the non-coupling region (Ct_Dm_G) is longer than a distance between the second reflection layer (62) and the second pixel electrode (131B) in the second pixel contact region (Ct_Px_B), and a distance between the first reflection layer (62) and the first pixel electrode (131G) in the first pixel contact region (Ct_Px_G) is substantially equal to a distance between the second reflection layer (62) and the second pixel electrode (131B) in the second pixel contact region (Ct_Px_B).

With the seventh aspect, the height of the second pixel electrode (131B) at the second pixel contact region (Ct_Px_B) is aligned with the height of the first pixel electrode (131G) at the first pixel contact region (Ct_Px_G), which makes it possible to suppress the abnormal light emission due to the step at the front surface.

Note that the pixel electrode 131B serves as one example of the second pixel electrode. The OLED 130B serves as one example of the second light emitting element. The reflection layer 62 at the pixel portion 110 for B serves as one example of the second reflection layer. The relay layer 71 at the pixel portion 110 for B serves as one example of the second relay layer.

### Note 8

An electro-optical device (10) according to a specific aspect (eighth aspect) of the seventh aspect includes: a third light emitting element (130R) including the common electrode (133), a third pixel electrode (133R), and the light emitting layer (132); a third reflection layer (62) provided between the substrate (60) and the third pixel electrode (131R); and a third relay layer (71) configured to electrically couple the third reflection layer (62) and the third pixel electrode (131R), in which, in a region where the third pixel electrode (131R) and the light emitting layer (132) overlap with each other in plan view, the third light emitting element (130R) includes: a third light emitting region (R) where the third pixel electrode (131R) and the light emitting layer (132) are in contact with each other; and a third pixel contact region (Ct_Px_R) where the third pixel electrode (131R) and the third relay layer (71) overlap with each other in plan view, in a direction of a thickness of the substrate (60), a distance between the first reflection layer (62) and the first pixel electrode (131G) in the non-coupling region (Ct_Dm_G) is longer than a distance between the third reflection layer (62) and the third pixel electrode (131R) in the third pixel contact region (Ct_Px_R), and a distance between the first reflection layer (62) and the first pixel electrode (131G) in the first pixel contact region (Ct_Px_G) is substantially equal to a distance between the third reflection layer (62) and the third pixel electrode (131R) in the third pixel contact region (Ct_Px_R).

With the eighth aspect, the height of the third pixel electrode (131R) in the third pixel contact region (Ct_Px_R) is aligned with the height of the first pixel electrode (131G) in the first pixel contact region (Ct_Px_G). This makes it possible to suppress the abnormal light emission due to a step at the front surface.

Note that the pixel electrode 131R serves as one example of the third pixel electrode. The OLED 130R serves as one example of the third light emitting element. The reflection layer 62 at the pixel portion 110 for B serves as one example of the third reflection layer. The relay layer 71 at the pixel portion 110 for B serves as one example of the third relay layer.

### Note 9

In an electro-optical device (10) according to a specific aspect (ninth aspect) of the eighth aspect, the first light emitting element (130G) includes a fourth light emitting region (G2), the non-coupling region (Ct_Dm_G) is provided between the first light emitting region (G1), the second light emitting region (B), the third light emitting region (R), and the fourth light emitting region (G2) in plan view, and a distance (L2) between the non-coupling region (Ct_Dm_G) and the fourth light emitting region (G2) is shorter than a distance (L3) between the non-coupling region (Ct_Dm_G) and the third light emitting region (R).

With the ninth aspect, the area of the first light emitting element (130G) is a sum of areas of the first light emitting region (G1) and the fourth light emitting region (G2). This makes it possible to enhance the visibility. In addition, with the ninth aspect, the non-coupling region (Ct_Dm_G) is spaced apart from the third light emitting region (R) and is close to the fourth light emitting region (G2). This makes it possible to make the abnormal light emission at or around the non-coupling region (Ct_Dm_G) less likely to be visually recognized.

### Note 10

In an electro-optical device (10) according to a specific aspect (tenth aspect) of any one of the second to fifth aspects, no insulating layer is provided between the first relay layer (71) and the first pixel electrode (131G), and an insulating layer (67, 68) is provided between the dummy relay layer (71D) and the first pixel electrode (131G).

With the tenth aspect, the insulating layer (67, 68) is provided. This makes it possible to increase the distance between the dummy relay layer (71D) and the first pixel electrode (131G).

### Note 11

An electro-optical device (10) according to a specific aspect (eleventh aspect) of the eighth aspect or ninth aspect includes: an insulating layer (68) having a first layer thickness and provided in the first light emitting region (G) between the first reflection layer (62) and the first pixel electrode (131G); and an insulating layer (67, 68) having a second layer thickness greater than the first layer thickness and provided in the third light emitting region (R) between the third reflection layer (62) and the third pixel electrode (131R), in which a first optical distance (LG) between the common electrode (133) and the first reflection layer (62) in the first light emitting region (G) is longer than a second optical distance (LB) between the common electrode (133) and the second reflection layer (62) in the second light emitting region (B), and the first optical distance (LG) is shorter than a third optical distance (LR) between the common electrode (133) and the third reflection layer (62) in the third light emitting region (R). With the eleventh aspect, it is possible to cause the wavelength of the light outputted from the light emitting region to be long in the order from the third light emitting region (R), the first light emitting region (G), and the second light emitting region (B).

### Note 12

In an electro-optical device (10) according to a specific aspect (twelfth aspect) of the eleventh aspect, light emitted from the non-coupling region (Ct_Dm_G) is light having a wavelength region that resonates with the third optical distance (LR). With the twelfth aspect, the light emitted from the non-coupling region (Ct_Dm_G) is blocked by the first color layer (Cf_G) at a wavelength shorter than the wavelength of the light.

### Note 13

An electronic device (300) according to the thirteenth aspect includes the electro-optical device (10) according to any one of the first to twelfth aspects.

### Note 14

An electro-optical device (10) according to another fourteenth aspect includes:
a first pixel portion (110G) provided at the substrate (10) with the light emitting layer (132) being interposed between the first pixel electrode (131G) and the common electrode (133) and configured to output a first color from the first light emitting region (G); and
a second pixel portion (110R) provided at the substrate (60) with the light emitting layer (132) being interposed between the second pixel electrode (131R) and the common electrode (133) and configured to output a second color having a wavelength longer than the first color from the second light emitting region (R), in which
the first pixel portion (110G) includes, in plan view:
a first pixel contact region (Ct_Px_G) where the first pixel electrode (131G) is coupled to the lower wiring line (61); and
a dummy contact region (Ct_Dm_G) where the first pixel electrode (131G) is not coupled to the lower wiring line (61),
the second pixel portion (110R) includes a second pixel contact region (Ct_Px_R) where the second pixel electrode (131R) is coupled to the lower wiring line (61) in plan view,
when viewed in cross section, the first pixel electrode (131G) at the dummy contact region (Ct_Dm_G) is higher than the pixel electrode (131G) at the first pixel contact region (Ct_Px_G) and is also higher than the second pixel electrode (131R) at the second pixel contact region (Ct_Px_R), when the substrate (60) is set as a reference, and
a color layer (Cf_G) corresponding to the first color is provided at a portion that overlaps with the dummy contact region (Ct_Dm_G) in plan view.

With this thirteenth aspect, when a portion of the electro-optical device (10) is pressed, the dummy contact region (Ct_Dm_G) works as a stopper to suppress this pressing. In addition, even when the thickness of the light emitting layer 132 reduces due to the pressing, the thickness reduced portion is limited to the vicinity of the dummy contact region (Ct_Dm_G). For this reason, with the first aspect, even when abnormal light emission occurs at and around the dummy contact region (Ct_Dm_G), the abnormal light emission is blocked by the color layer (Cf_G). Thus, with the first aspect, the abnormal light emission is prevented from being visually recognized by an observer, which makes it possible to suppress a deterioration in the display quality.

What is claimed is:

1. An electro-optical device comprising:
a substrate;
a first light emitting element including a common electrode, a first pixel electrode, and a light emitting layer;
a first reflection layer provided between the substrate and the first pixel electrode; and
a first relay layer configured to electrically couple the first reflection layer and the first pixel electrode, wherein
the first light emitting element includes, in plan view, in a region where the first pixel electrode and the light emitting layer overlap with each other:
a first light emitting region where the first pixel electrode and the light emitting layer are in contact with each other;
a first pixel contact region where the first pixel electrode and the first relay layer overlap with each other in plan view; and
a non-coupling region disposed at an outside of the first light emitting region in plan view and differing from the first pixel contact region,
in a direction of a thickness of the substrate, a distance between the first reflection layer and the first pixel electrode in the non-coupling region is longer than a distance between the first reflection layer and the first pixel electrode in the first pixel contact region, and
a first color layer is provided so as to overlap with the non-coupling region in plan view and is configured to block light emitted from the non-coupling region.

2. The electro-optical device according to claim 1 comprising:
a dummy relay layer provided between the first reflection layer and the first pixel electrode and not electrically coupled to at least one of the first reflection layer and the first pixel electrode, and
the non-coupling region is a region where the first pixel electrode, the dummy relay layer, the light emitting layer, and the common electrode overlap in plan view.

3. The electro-optical device according to claim 2, wherein
the dummy relay layer is not electrically coupled to the first reflection layer, and is not electrically coupled to the first pixel electrode.

4. The electro-optical device according to claim 2, wherein
the dummy relay layer is electrically coupled to the first reflection layer, and is not electrically coupled to the first pixel electrode.

5. The electro-optical device according to claim 2, wherein
the dummy relay layer is not electrically coupled to the first reflection layer, and is electrically coupled to the first pixel electrode.

6. The electro-optical device according to claim 2, wherein
the dummy relay layer includes:
a first dummy relay layer electrically coupled to the first pixel electrode; and
a second dummy relay layer electrically coupled to the first reflection layer, and
the first dummy relay layer and the second dummy relay layer are not electrically coupled to each other.

7. The electro-optical device according to claim 1 comprising:
a second light emitting element including the common electrode, a second pixel electrode, and the light emitting layer;
a second reflection layer provided between the substrate and the second pixel electrode; and
a second relay layer configured to electrically couple the second reflection layer and the second pixel electrode, wherein,
the second light emitting element includes, in a region where the second pixel electrode and the light emitting layer overlap with each other in plan view:
a second light emitting region where the second pixel electrode and the light emitting layer are in contact with each other; and
a second pixel contact region where the second pixel electrode and the second relay layer overlap with each other in plan view,
in the direction of the thickness of the substrate, the distance between the first reflection layer and the first pixel electrode in the non-coupling region is longer than a distance between the second reflection layer and the second pixel electrode in the second pixel contact region, and
the distance between the first reflection layer and the first pixel electrode in the first pixel contact region is substantially equal to the distance between the second reflection layer and the second pixel electrode in the second pixel contact region.

8. The electro-optical device according to claim 7 comprising:
a third light emitting element including the common electrode, a third pixel electrode, and the light emitting layer;
a third reflection layer provided between the substrate and the third pixel electrode; and
a third relay layer configured to electrically couple the third reflection layer and the third pixel electrode, wherein,
the third light emitting element includes, in a region where the third pixel electrode and the light emitting layer overlap with each other in plan view:
a third light emitting region where the third pixel electrode and the light emitting layer are in contact with each other; and
a third pixel contact region where the third pixel electrode and the third relay layer overlap with each other in plan view,
in the direction of the thickness of the substrate, the distance between the first reflection layer and the first pixel electrode in the non-coupling region is longer than a distance between the third reflection layer and the third pixel electrode in the third pixel contact region, and
the distance between the first reflection layer and the first pixel electrode in the first pixel contact region is substantially equal to the distance between the third reflection layer and the third pixel electrode in the third pixel contact region.

9. The electro-optical device according to claim 8, wherein
the first light emitting element includes a fourth light emitting region,
the non-coupling region is provided between the first light emitting region, the second light emitting region, the third light emitting region, and the fourth light emitting region in plan view, and
a distance between the non-coupling region and the fourth light emitting region is shorter than a distance between the non-coupling region and the third light emitting region.

10. The electro-optical device according to claim 2, wherein
no insulating layer is provided between the first relay layer and the first pixel electrode, and
an insulating layer is provided between the dummy relay layer and the first pixel electrode.

11. The electro-optical device according to claim 8 comprising:
an insulating layer having a first layer thickness and provided between the first reflection layer and the first pixel electrode in the first light emitting region; and
an insulating layer having a second layer thickness greater than the first layer thickness and provided between the third reflection layer and the third pixel electrode in the third light emitting region, wherein
a first optical distance between the common electrode and the first reflection layer in the first light emitting region is longer than a second optical distance between the common electrode and the second reflection layer in the second light emitting region, and
the first optical distance is shorter than a third optical distance between the common electrode and the third reflection layer in the third light emitting region.

12. The electro-optical device according to claim 11, wherein
light emitted from the non-coupling region is light having a wavelength region that resonates with the third optical distance.

13. An electronic device comprising the electro-optical device according to claim 1.
